(19) United States
(12) Patent Application Publication
(10) Pub. No.: US 2024/0305705 A1
(43) Pub. Date: Sep. 12, 2024

(54) ELECTRONIC DEVICE COMPRISING GROUND STRUCTURE

(71) Applicant: SAMSUNG ELECTRONICS CO., LTD., Suwon-si (KR)

(72) Inventors: Wonho LEE, Suwon-si (KR); Junghyeon KIM, Suwon-si (KR); Igor IVANOV, Suwon-si (KR); Youngmin JI, Suwon-si (KR); Myunghoon KWAK, Suwon-si (KR); Sanggon SHIN, Suwon-si (KR); Junyoung LEE, Suwon-si (KR); Yangwook KIM, Suwon-si (KR); Changryong HEO, Suwon-si (KR)

(21) Appl. No.: 18/666,055

(22) Filed: May 16, 2024

Related U.S. Application Data
(63) Continuation of application No. PCT/KR2022/015955, filed on Oct. 19, 2022.

(30) Foreign Application Priority Data
Nov. 16, 2021 (KR) 10-2021-0157507
Dec. 20, 2021 (KR) 10-2021-0182679

(51) Int. Cl. H04M 1/02; H01Q 1/24; H05K 9/00

(52) U.S. Cl. CPC H04M 1/0237; H01Q 1/243; H04M 1/0268; H04M 1/0277; H05K 9/0064

(57) ABSTRACT

According to an embodiment of the present disclosure, an electronic device is provided. The electronic device may comprise: a housing including a second housing and a first housing slidable with respect to the second housing; a display configured such that at least a portion of the display is unrolled based on the sliding of the first housing; a printed circuit board arranged inside the housing; a ground structure comprising a conductive material and including an elastic region configured to provide a force to the first housing, and electrically connect the printed circuit board to the second housing; and at least one rail structure including a rail arranged inside the second housing parallel to the sliding direction of the first housing, and in contact with the ground structure while the first housing is in a sliding state or a stopped state with respect to the second housing. The at least one rail structure may comprise a first region and a second region that protrudes more than the first region toward the ground structure.

### CROSS-REFERENCE TO RELATED APPLICATIONS

This application is a continuation of International Application No. PCT/KR2022/015955 designating the United States, filed on Oct. 19, 2022, in the Korean Intellectual Property Receiving Office and claiming priority to Korean Patent Application Nos. 10-2021-0157507, filed on Nov. 16, 2021, and 10-2021-0182679, filed on Dec. 20, 2021, in the Korean Intellectual Property Office, the disclosures of each of which are incorporated by reference herein in their entireties.

### BACKGROUND

### Field

The disclosure relates to an electronic device including a ground structure.

### Description of Related Art

With the development of information and communication technology and semiconductor technology, various functions are packed in one portable electronic device. For example, an electronic device may implement not only communication functions but also entertainment functions, such as playing games, multimedia functions, such as playing music and videos, communication and security functions for mobile banking, and scheduling and e-wallet functions. These electronic devices have been downsized to be conveniently carried by users.

As mobile communication services extend up to multimedia service sectors, electronic devices require a larger display to allow users satisfactory use of multimedia services as well as voice call or text messaging services. This, however, trades off the trend of electronic devices being compact.

### SUMMARY

According to an example embodiment of the disclosure, an electronic device may comprise: a housing including a first housing and a second housing slidable with respect to the second housing, a display configured so that at least a portion thereof is unrollable based on the slide of the first housing, a printed circuit board disposed in the housing, a ground structure including an elastic area configured to provide a force to the first housing and electrically connecting the printed circuit board and the second housing, and at least one rail structure comprising a rail disposed, inside the second housing, parallel to a sliding direction of the first housing and configured to contact the ground structure while the first housing is in a state of sliding with respect to the second housing or in a stationary state. The at least one rail structure may include a first area and a second area protruding toward the ground structure as compared with the first area.

According to an example embodiment of the disclosure, an electronic device may comprise: a housing including a first housing and a second housing configured to guide a slide of the first housing, a display configured so that at least a portion thereof is unrollable based on the slide of the first housing, a printed circuit board disposed in the first housing, a ground structure including a ground connected to the first housing and electrically connected to the printed circuit board, and a rail structure including a rail connected to the second housing and configured to guide the slide of the first housing with respect to the second housing. The rail structure may include a protruding portion protruding toward the first housing and formed to correspond to a shape of the ground structure.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a diagram illustrating an electronic device in a closed state, according to various embodiments;

FIG. 3 is a diagram illustrating an electronic device in an open state, according to various embodiments;

FIG. 4 is an exploded perspective view illustrating an electronic device according to various embodiments;

FIG. 5A is a diagram illustrating an electronic device in a closed state without a display, according to various embodiments;

FIG. 5B is a diagram illustrating an electronic device in an open state without a display according to various embodiments;

FIG. 6 is a perspective view illustrating a ground structure according to various embodiments;

FIG. 7 is an exploded perspective view illustrating a ground structure according to various embodiments;

FIG. 8 is a perspective view illustrating a ground structure according to various embodiments;

FIG. 9 is a perspective view illustrating an electronic device including a rail structure and a second housing according to various embodiments;

FIG. 10 is a cross-sectional view illustrating an electronic device according to various embodiments;

FIGS. 11A and 11B are cross-sectional views taken along line A-A′ of FIG. 9 according to various embodiments;

FIG. 12 is a perspective view illustrating an electronic device including a rail structure including a protruding area and a second housing according to various embodiments;

FIG. 13 is a diagram illustrating front view of the rail structure of FIG. 12, according to various embodiments;

FIG. 14 is a cross-sectional view illustrating an electronic device including the rail structure and the second housing of FIG. 12, according to various embodiments;

FIG. 15A is a cross-sectional view taken along line B-B′ of FIG. 14 according to various embodiments;

FIG. 15B is a cross-sectional view taken along line C-C′ of FIG. 14 according to various embodiments;

FIGS. 16A, 16B, and 16C are diagrams illustrating a rotation area of a ground structure according to various embodiments;

FIG. 17 is a perspective view illustrating an electronic device including a ground structure and a first housing according to various embodiments;

FIG. 18 is a cross-sectional view illustrating an electronic device including a ground structure and a first housing according to various embodiments;

FIG. 19 is a perspective view illustrating a ground structure according to various embodiments;

FIG. 20 is a perspective view illustrating an electronic device including a ground structure and a second housing including a rail structure according to various embodiments; and

FIG. 21 is a cross-sectional view illustrating an electronic device according to various embodiments.

### DETAILED DESCRIPTION

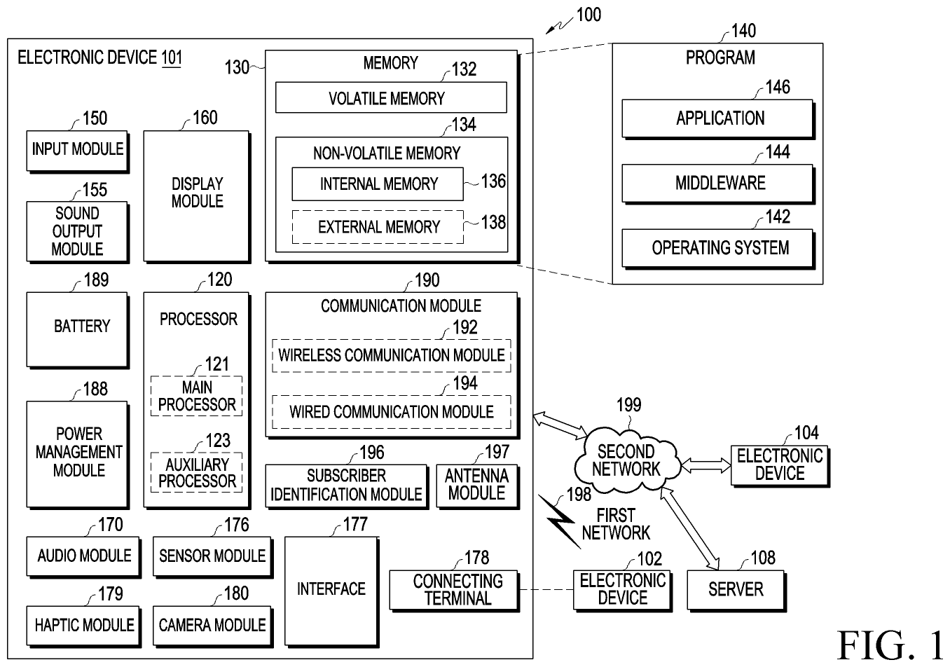

FIG. 1 is a block diagram illustrating an electronic device in a network environment according to various embodiments of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal According to an embodiment, the display module 160 may include a first display module 351 corresponding to the user's left eye and/or a second display module 353 corresponding to the user's right eye., a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module may include an antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

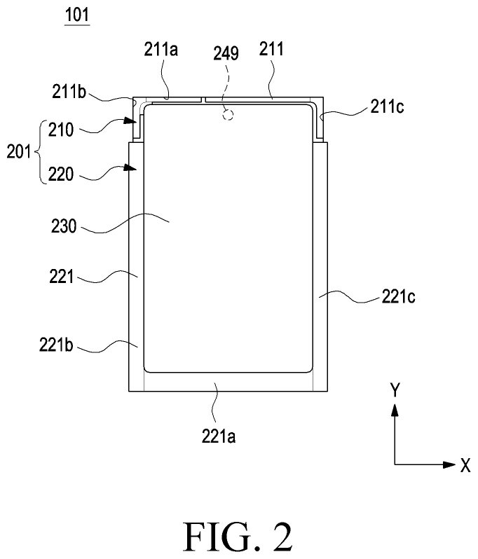

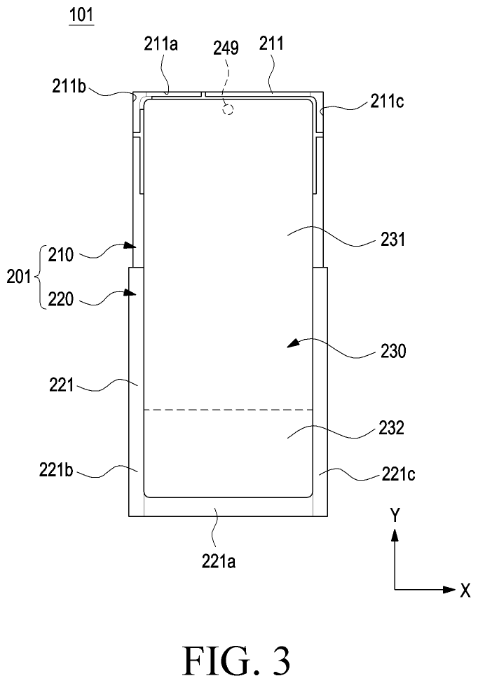

FIG. 2 is a diagram illustrating an electronic device in a closed state, according to various embodiments. FIG. 3 is a diagram illustrating an electronic device in an open state, according to various embodiments. For example, FIG. 2 is a diagram illustrating a state in which a second display area 232 is received in a housing 201. FIG. 3 is a diagram illustrating a state in which at least a portion of the second display area 232 is visible to the outside of the housing 201.

The state shown in FIG. 2 may be denoted as a first housing 210 being closed with respect to a second housing 220, and the state shown in FIG. 2 may be denoted as the first housing 210 being open with respect to the second housing 220. According to an embodiment, the “closed state” or “opened state” may be defined as a closed or open state of the electronic device.

Referring to FIGS. 2 and 3, the electronic device 101 may include a housing 201. The housing 201 may include a second housing 220 and a first housing 210 that is movable with respect to the second housing 220. According to an embodiment, the electronic device 101 may be interpreted as having a structure in which the second housing 220 is slidably disposed on the first housing 210. According to an embodiment, the first housing 210 may reciprocate by a predetermined distance in the length direction (e.g., Y-axis direction) of the electronic device 101, with respect to the second housing 220. The configuration of the electronic device 101 of FIGS. 2 and 3 may be identical in whole or part to the configuration of the electronic device 101 of FIG. 1.

According to an embodiment, the first housing 210 may be referred to as a first structure, a slide part, or a slide housing, and may be disposed to reciprocate on the second housing 220. According to an embodiment, the second housing 220 may be referred to as, e.g., a second structure, a main part, or a main housing. The second housing 220 may receive at least a portion of the first housing 210 and may guide the slide of the first housing 210. According to an embodiment, the second housing 220 may receive various electrical/electronic components, such as a first circuit board (e.g., main circuit board) or a battery. According to an embodiment, at least a portion (e.g., the first display area 231) of the display 230 may be visible to the outside of the housing 201. According to an embodiment, another portion (e.g., the second display area 232) of the display 230 may be received into the inside of the second housing 220 (e.g., a slide-in motion) or be visible to the outside of the second housing 220 (e.g., a slide-out motion) as the first housing 210 moves (e.g., slides) with respect to the second housing 220. According to an embodiment, a motor, a speaker, a sim socket, and/or a second circuit board (e.g., sub circuit board) electrically connected with the first circuit board may be disposed in the first housing 210. The first circuit board (e.g., main circuit board) on which electrical components, such as an application processor (AP) and a communication processor (CP) are mounted may be disposed in the second housing 220.

According to an embodiment, the first housing 210 may include a slide cover 211. The slide cover 211 may be referred to as a slide plate or slide cover. According to an embodiment, the slide cover 211 may surround at least a portion (e.g., the first display area 231) of the display 230. According to an embodiment, the slide cover 211 may include first sidewalls 211a, 211b, and 211c to surround at least a portion of the display 230. According to an embodiment, the first sidewalls 211a, 211b, and 211c may extend from the slide cover 211. The first sidewalls 211a, 211b, and 211c may include a 1-2th sidewall 211b, a 1-3th sidewall 211c opposite to the 1-2th sidewall 211b, and a 1-1th sidewall 211a extending from the 1-2th sidewall 211b to the 1-3th sidewall 211c. According to an embodiment, the 1-1th sidewall 211a may be substantially perpendicular to the 1-2th sidewall 211b and/or the 1-3th sidewall 211c. According to an embodiment, in the closed state (e.g., FIG. 2) of the electronic device 101, the 1-2th sidewall 211b may face the 2-2th sidewall 221b of the second housing 220, and the 1-3th sidewall 211c may face the 2-3th sidewall 221c of the second housing 220. According to an embodiment, the slide cover 211, the 1-1th sidewall 211a, the 1-2th sidewall 211b, and/or the 1-3th sidewall 211c may be integrally formed. According to an embodiment, the slide cover 211, the 1-1th sidewall 211a, the 1-2th sidewall 211b, and/or the 1-3th sidewall 211c may be formed as separate housings and be combined or assembled.

According to an embodiment, the second housing 220 may include a cover member 211. The cover member 221 may be referred to as a main cover or a book cover. The cover member 221 may be formed to be open at one side (e.g., a front face) to receive (or surround) at least a portion of the first housing 210.

According to an embodiment, the second housing 220 may include second sidewalls 221a, 221b, and 221c to surround at least a portion of the first housing 210. According to an embodiment, the second sidewalls 221a, 221b, and 221c may extend from the cover member 221. According to an embodiment, the second sidewalls 221a, 221b, and 221c may include a 2-2th sidewall 221b, a 2-3th sidewall 221c opposite to the 2-2th sidewall 221b, and a 2-1th sidewall 221a extending from the 2-2th sidewall 221b to the 2-3th sidewall 221c. According to an embodiment, the 2-1th sidewall 221a may be substantially perpendicular to the 2-2th sidewall 221b and/or the 2-3th sidewall 221c . According to an embodiment, the 2-2th sidewall 221b may face the 1-2th sidewall 211b, and the 2-3th sidewall 221c may face the 1-3th sidewall 211c. For example, in the closed state (e.g., FIG. 2) of the electronic device 101, the 2-2th sidewall 221b may cover at least a portion of the 1-2th sidewall 211b, and the 2-3th sidewall 221c may cover at least a portion of the 1-3th sidewall 211c. According to an embodiment, the first housing 210 may be connected to the second housing 220 while being at least partially surrounded by the 2-1th sidewall 221a, the 2-2th sidewall 221b, and the 2-3th sidewall 221c and may be slid in the length direction (e.g., Y-axis direction) of the electronic device 101 while being guided by the second housing 220. According to an embodiment, the cover member 221, the 2-1th sidewall 221a, the 2-2th sidewall 221b, and/or the 2-3th sidewall 221c may be integrally formed. According to an embodiment, the second cover member 221, the 2-1th sidewall 221a, the 2-2th sidewall 221b, and/or the 2-3th sidewall 221c may be formed as separate housings and be combined or assembled.

According to an embodiment, the electronic device 101 may include a display 230. For example, the display 230 may be interpreted as a flexible display or a rollable display. According to an embodiment, the display 230 may slide based on a slide of the first housing 210. According to an embodiment, the display 230 may include, or be disposed adjacent to, a touch detection circuit, a pressure sensor capable of measuring the intensity (pressure) of a touch, and/or a digitizer that detects a magnetic field-type stylus pen. The configuration of the display 230 of FIGS. 2 and 3 may be identical in whole or part to the configuration of the display module 160 of FIG. 1.

According to an embodiment, the display 230 may include a first display area 231 and a second display area 232. According to an embodiment, the first display area 231 may be an area that is always visible from the outside. According to an embodiment, the second display area 232 may extend from the first display area 231, and the second display area 232 may be inserted or received in, or visible to the outside of, the second housing 220 as the first housing 210 slides. According to an embodiment, the first display area 231 may be seated on a portion (e.g., the slide cover 211) of the first housing 210.

According to an embodiment, the second display area 232 may be substantially moved while being guided by the multi-bar structure mounted in the first housing 210 and may be thus received in, or visible to the outside of, the second housing 220 or a space formed between the first housing 210 and the second housing 220. According to an embodiment, the second display area 232 may be moved based on the slide of the first housing 210 in the length direction (e.g., Y-axis direction). For example, at least a portion of the second display area 232 may be unfolded or rolled together with the multi-bar structure based on a slide of the first housing 210.

According to an embodiment, when viewed from above the first housing 210, if the first housing 210 moves from the closed state to the open state, the second display area 232 may be gradually expanded to be visible to the outside of the first housing 210 to be substantially coplanar with the first display area 231. In an embodiment, the second display area 232 may be at least partially received in the first housing 210 and/or the second housing 220.

According to an embodiment, the electronic device 101 may include at least one key input device, a connector hole, an audio module (e.g., the audio module 170 of FIG. 1) or a camera module (e.g., the camera module 180 of FIG. 1). Although not shown, the electronic device 101 may further include an indicator (e.g., a light emitting diode (LED) device) or various sensor modules.

According to an embodiment, the key input device may be positioned in the first housing 210 and/or the second housing 220. According to an embodiment, the electronic device 101 may include a key input device (not shown), e.g., a home key button or a touchpad disposed around the home key button.

According to an embodiment, the connector hole may be omitted or may receive a connector (e.g., a universal serial bus (USB) connector) for transmitting and receiving power and/or data with an external electronic device. According to an embodiment, the connector hole may be positioned between the first housing 210 and/or the second housing 220. The electronic device 101 may include a plurality of connector holes, and some of the plurality of connector holes may function as connector holes for transmitting/receiving audio signals with an external electronic device.

According to an embodiment, the audio modules may include at least one speaker hole and/or at least one microphone hole. At least one of the speaker holes may be provided as an external speaker hole. At least one of the speaker holes may be provided as a receiver hole for voice call. The electronic device 101 may include a microphone for obtaining sound. The microphone may obtain external sound of the electronic device 100 through the microphone hole. According to an embodiment, the electronic device 101 may include a plurality of microphones to detect the direction of sound. According to an embodiment, the electronic device 101 may include an audio module in which the speaker holes and the microphone hole are implemented as one hole or may include a speaker without the speaker hole (e.g., a piezo speaker).

According to an embodiment, the camera module 249 may include at least one of a wide-angle camera, a telephoto camera, or a close-up camera. According to an embodiment, the electronic device 200 may measure the distance to the subject by including an infrared projector and/or an infrared receiver. The camera module 249 may include one or more lenses, an image sensor, and/or an image signal processor. The electronic device 101 may further include another camera module (e.g., a rear camera) that captures the subject in a direction opposite to the camera module 249 (e.g., a front camera). For example, the camera module 249 may be disposed around the first display area 231 or in an area overlapping the first display area 231. If disposed in an area overlapping the display 230, the camera module 249 may capture the subject through the display 230. The other camera module may be positioned in the second housing 220 and may capture a subject in a direction opposite to the first display area 231 of the display 230.

According to an embodiment, an indicator (e.g., an LED device) of the electronic device 101 may be disposed on the first housing 210 and/or the second housing 220, and the indicator may include a light emitting diode to provide state information about the electronic device 101 as a visual signal. The sensor module (e.g., the sensor module 176 of FIG. 1) of the electronic device 101 may produce an electrical signal or data value corresponding to the internal operation state or external environment state of the electronic device. The sensor module may include, for example, a proximity sensor, a fingerprint sensor, or a biometric sensor (e.g., an iris/face recognition sensor or a heartrate monitor (HRM) sensor). In an embodiment, the electronic device 101 may include at least one of a gesture sensor, a gyro sensor, an atmospheric pressure sensor, a magnetic sensor, an accelerometer, a grip sensor, a color sensor, an infrared (IR) sensor, a temperature sensor, a humidity sensor, or an illuminance sensor.

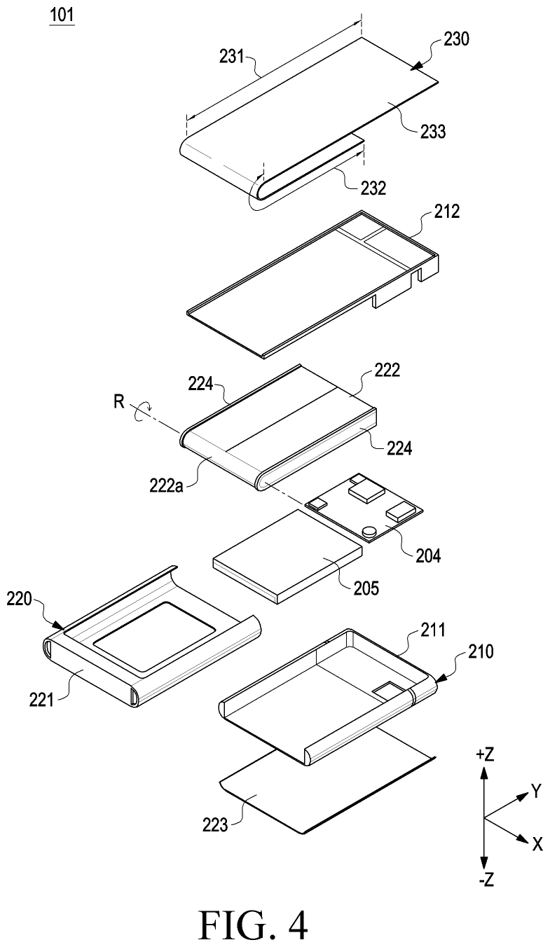

FIG. 4 is an exploded perspective view illustrating an electronic device according to various embodiments;

Referring to FIG. 4, an electronic device 101 may include a first housing 210, a second housing 220, and a display assembly 233. The configuration of the first housing 210, the second housing 220, and the display assembly 233 of FIG. 3 may be identical in whole or part to the configuration of the first housing 210, the second housing 220, and the display 230 of FIGS. 2 and 3.

According to an embodiment, the first housing 210 may include a slide cover 211 and a first plate 212. The slide cover 211 and the first plate 212 may linearly reciprocate in one direction (e.g., Y-axis direction) while being guided by the second housing 220. According to an embodiment, the first housing 210 may surround at least some of the components of the electronic device 101. For example, the printed circuit board 204 may be disposed in the first housing 210. For example, the printed circuit board 204 may be connected to the slide cover 211.

According to an embodiment, the slide cover 211 may protect the display 230 positioned on the first plate 212. For example, at least a portion of the display 230 may be positioned between the first plate 212 and the slide cover 211. According to an embodiment, the first plate 212 and the slide cover 211 may be formed of a metal material and/or a non-metal (e.g., polymer) material.

According to an embodiment, the first plate 212 may support at least a portion of the display 230 (e.g., the first display area 231). According to an embodiment, the first plate 212, along with the slide cover 211, may slide with respect to the second housing 220. According to an embodiment, the first plate 212 may be connected to the slide cover 211.

According to various embodiments, the second housing 220 may include a cover member 221, a second plate 222, and a rear plate 223. According to an embodiment, the cover member 221 may receive components (e.g., the battery 205 (e.g., the battery 189 of FIG. 1)) of the electronic device 101 and may protect the components of the electronic device 101. The configuration of the cover member 221 may be identical in whole or part to the configuration of the cover member 221 of FIG. 2 and/or FIG. 3.

According to an embodiment, the second plate 222 may support at least a portion of the display 230 (e.g., the second display area 232). For example, the second plate 222 may include a curved surface 222a. The second display area 232 of the display 230 may be positioned on the curved surface 222a. According to an embodiment, the second display area 232 may be referred to as a display supporting plate.

According to an embodiment, the rear plate 223 may substantially form at least a portion of the exterior of the second housing 220 or the electronic device 101. For example, the rear plate 223 may be coupled to the outer surface of the cover member 221. According to an embodiment, the rear plate 223 may be integrally formed with the cover member 221. According to an embodiment, the rear plate 223 may provide a decorative effect on the exterior of the electronic device 101. The second plate 222 and the cover member 221 may be formed of at least one of a metal or a polymer, and the rear plate 223 may be formed of at least one of metal, glass, synthetic resin or ceramic. According to an embodiment, the second plate 222, the cover member 221 and/or the rear plate 223 may be formed of a material that transmits light at least partially (e.g., the auxiliary display area). For example, in a state in which a portion of the display 230 (e.g., the second display area 232) is received in the electronic device 101, the electronic device 101 may output visual information using the second display area 232. The auxiliary display area may be a portion of the second plate 222, the cover member 221, and/or the rear plate 223 in which the display 230 received in the second housing 220 is positioned.

According to an embodiment, the second housing 220 may include a guide rail 224. According to an embodiment, the guide rail 224 may be connected to the second plate 222. At least a portion (e.g., the multi-bar structure) of the display assembly 233 may move along the guide rail 224.

According to an embodiment, the display assembly 233 may include a display (e.g., the display 230 of FIGS. 2 and/or 3) and a multi-bar structure (not shown) supporting the display 230. For example, the multi-bar structure may be connected to the display 230 and may move together with the display 230. According to an embodiment, at least a portion of the display assembly 233 may be positioned between the second plate 212 and the slide cover 211. According to an embodiment, as the first housing 210 slides, the multi-bar structure may move with respect to the second housing 220. In the closed state (e.g., FIG. 2) of the multi-bar structure, most of the structure may be received in the second housing 220. According to an embodiment, at least a portion of the multi-bar structure may move corresponding to the curved surface 220a positioned at the edge of the second plate 222.

According to an embodiment, the multi-bar structure may include a plurality of bars or rods. The plurality of rods may extend in a straight line and be disposed parallel to the rotational axis R formed by the curved surface 222a, and the plurality of rods 214 may be arranged along a direction perpendicular to the rotational axis R (e.g., the direction along which the first housing 210 slides).

According to an embodiment, each rod may move along the guide rail 224 while remaining parallel to another adjacent rod. According to an embodiment, as the first housing 210 slides, the plurality of rods may be arranged to form a curved shape or may be arranged to form a planar shape. For example, as the first housing 210 slides, a portion of the multi-bar structure facing the curved surface 222a may form a curved surface, and another portion of the multi-bar structure not facing the curved surface 222a may form a flat surface. According to an embodiment, the second display area 232 of the display 230 may be mounted or supported on the multi-bar structure, and in the open state (e.g., FIG. 3), at least a portion of the second display area 232, together with the first display area 231, may be visible to the outside of the second housing 220. In the state in which the second display area 232 is visible to the outside of the second housing 220, the multi-bar structure may substantially form a flat surface, thereby supporting or maintaining the second display area 232 in the flat state. According to an embodiment, the multi-bar structure may be replaced with a bendable integral supporting member (not shown). According to an embodiment, the multi-bar structure may be interpreted as a display supporting multi-bar or articulated hinge structure.

According to various embodiments, the guide rail 224 may guide the movement of the plurality of rods. According to an embodiment, the guide rail 224 may include a left guide rail adjacent to the 1-2th sidewall (e.g., the 1-2th sidewall 211b in FIG. 3) and a right guide rail adjacent to the 1-3th sidewall (e.g., the 1-3th sidewall 211c). According to an embodiment, the guide rail 224 may include a grooved rail formed inside the guide rail 224 and a protruding portion positioned inside the guide rail 224 and at least partially surrounded by the grooved rail. According to an embodiment, the multi-bar structure may be positioned between the left guide rail and the right guide rail, and may move while remaining engaged with the left guide rail and the right guide rail. For example, upper and/or lower end portions of the plurality of rods may slide along the rail while fitted into the rail.

According to an embodiment, when the electronic device 101 is opened (e.g., a slide-out operation), the size of the area where the display 230 is visible to the outside may be increased. For example, the first plate 212 connected to a motor (not shown) may slide out using a gear structure (e.g., a rack gear and/or a pinion gear) by driving the motor (e.g., driving for sliding out the display) and/or an external force provided by the user, and the protruding portion inside the guide rail 224 may push out the upper end portion and/or the lower end portion of the plurality of rods. Accordingly, the display 230 may be unfoldable or unrollable to the front surface.

According to an embodiment, when the electronic device 101 is closed (e.g., a slide-in operation), the size of the area where the display 230 is visible to the outside may be reduced. For example, by the driving of the motor (e.g., driving for sliding in the display) and/or the external force provided by the user, the first plate 212 may slide in, and the outer portion of the guide rail 224 may push the upper end portion and/or the lower end portion of the plurality of rods. Accordingly, the unfolded display 230 may be received between the first plate 212 and the slide cover 211.

Accordingly, the unfolded or unrolled display 230 may be received between the first plate 212 and the slide cover 211. A processor, memory, and/or interface may be mounted on the printed circuit board 204 which is the main board. The processor may include one or more of, e.g., a central processing unit, an application processor, a graphic processing device, an image signal processing, a sensor hub processor, or a communication processor.

According to an embodiment, the printed circuit board 204 may include a flexible printed circuit board type radio frequency cable (FRC). According to an embodiment, the printed circuit board 204 may be disposed in the slide cover 211 and may be electrically connected to an antenna module (e.g., the antenna module 197 of FIG. 1) connected to the second housing 220.

According to an embodiment, the battery 205 may be a device for supplying power to at least one component of the electronic device 101. The battery 189 may include, e.g., a primary cell which is not rechargeable, a secondary cell which is rechargeable, or a fuel cell. At least a portion of the battery 205 may be disposed on substantially the same plane as the printed circuit board 204. The battery 205 may be integrally or detachably disposed inside the electronic device 101. According to an embodiment, the battery 205 may be formed of a single embedded battery or may include a plurality of removable batteries.

The electronic device 101 disclosed in FIGS. 2, 3 and 4 has a rollable or slidable appearance but the present disclosure is not limited thereto. According to an embodiment (not shown), at least a portion of the illustrated electronic device may be rolled up in a scroll shape. According to an embodiment (not shown), the electronic device may be a bar-shaped electronic device.

Referring to FIGS. 2, 3 and 4, when viewed from the front of the electronic device 101, the display 230 may be unfolded or unrolled in the length direction (e.g., Y-axis direction) of the electronic device 101. However, the structure of the electronic device 101 is not limited thereto. For example, according to an embodiment, the display 230 may be unfolded or unrolled in the width direction (e.g., the X-axis direction) (e.g., the right or left direction) of the electronic device 101.

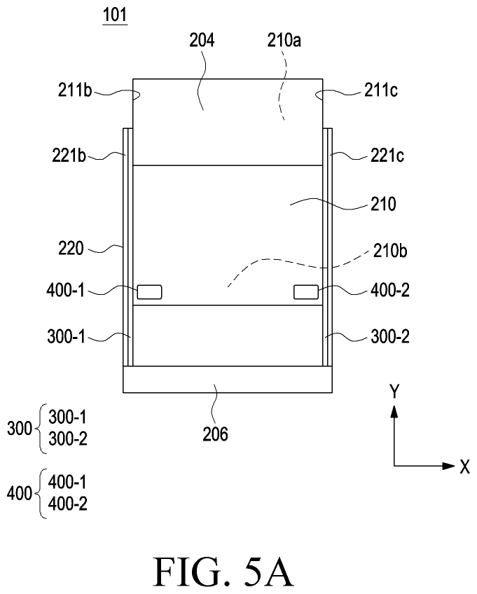

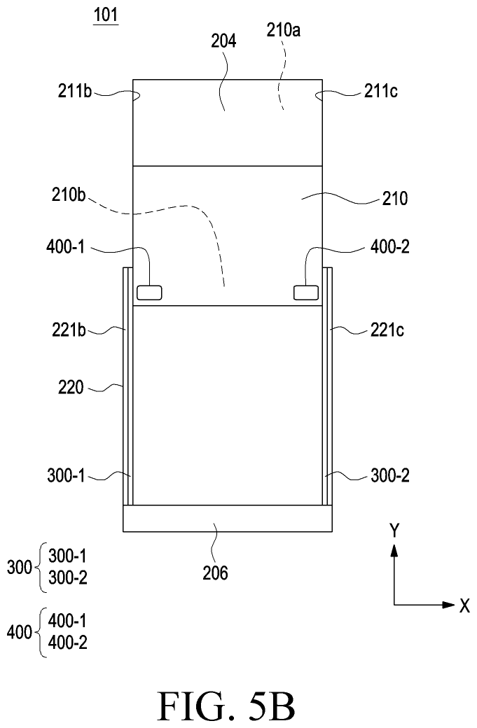

FIG. 5A is a diagram illustrating an electronic device in a closed state without a display, according to various embodiments. FIG. 5B is a diagram illustrating an electronic device without a display in an open state according to various embodiments.

Referring to FIGS. 5A and 5B, an electronic device 101 may include a printed circuit board 204, a first housing 210, a second housing 220, a rail structure 300, and a ground structure 400. The configuration of the printed circuit board 204, the first housing 210, and the second housing 220 of FIGS. 5A and 5B may be identical in whole or part to the configuration of the printed circuit board 204, the first housing 210, and the second housing 220 of FIG. 4.

According to an embodiment, the rail structure 300 may guide the slide of the first housing 210. For example, the rail structure 300 may face at least a portion (e.g., the 1-2th side wall 211b and the 1-3th side wall 211c) of the first housing 210. The first housing 210 may slide with respect to the second housing 220 while facing or contacting the rail structure 300.

According to an embodiment, the rail structure 300 may be disposed on the second housing 220. For example, the rail structure 300 may be disposed on the 2-2th side wall 221b and the 2-3th side wall 221c of the cover member 221. According to an embodiment, the rail structure 300 may include a plurality of rail structures 300-1 and 300-2. For example, the rail structure 300 may include a first rail structure 300-1 disposed on the 2-2th side wall 221b and a second rail structure 300-2 spaced apart from the first rail structure 300-1 and disposed on the 2-3th side wall 221c. The first rail structure 300-1 may be disposed substantially parallel to the second rail structure 300-2. According to an embodiment, the rail structure 300 may be electrically connected to the ground structure 400 and the antenna module 206.

According to an embodiment, the ground structure 400 may electrically connect a component positioned in the first housing 210 and a component positioned in the second housing 220. For example, the ground structure 400 may electrically connect the printed circuit board 204 disposed in the first housing 210 and the antenna module 206 connected to the second housing 220.

According to an embodiment, a component (e.g., the antenna module 206) positioned in the second housing 220 may be electrically connected to the printed circuit board 204 positioned in the first housing 210 through the ground structure 400 and the rail structure 300, and may use at least a portion of the printed circuit board 204 as a ground for providing a reference potential. According to an embodiment, as the antenna module 206 uses the printed circuit board 204 as a ground, the area of the ground used by the antenna module 206 may be increased, and the radiation performance of the electronic device 101 may be enhanced.

According to an embodiment, the ground structure 400 may include a first ground structure 400-1 facing at least a portion of the first rail structure 300-1 and a second ground structure 400-2 facing at least a portion of the second rail structure 300-2. According to an embodiment, the first ground structure 400-1 may contact the first rail structure 300-1 and may be electrically connected to the first rail structure 300-1, and the second ground structure 400-2 may contact the second rail structure 300-2 and may be electrically connected to the second rail structure 300-2. According to an embodiment, the first ground structure 400-1 may be disposed adjacent to the 1-2th side wall 211b and/or the 2-2th side wall 221b, and the second ground structure 400-2 may be disposed adjacent to the 1-3th side wall 211c and/or the 2-3th side wall 221c.

According to an embodiment, at least a portion of the rail structure 300 and at least a portion of the ground structure 400 may be formed of a conductive material. For example, the rail structure 300 and/or the ground structure 400 may include metal (e.g., stainless steel, aluminum, copper, and/or silver).

According to an embodiment, the ground structure 400 may be positioned under the first housing 210. For example, the first housing 210 may include a first portion 210a facing outward of the electronic device 101 and a second portion 210b opposite to the first portion 210a and facing the second housing 220. The ground structure 400 may be connected to the second portion 210b. According to an embodiment, the ground structure 400 may be positioned between the printed circuit board 204 and the slide cover 211.

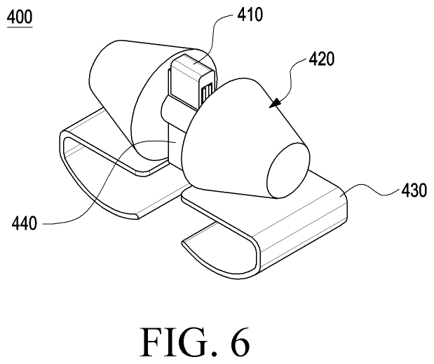

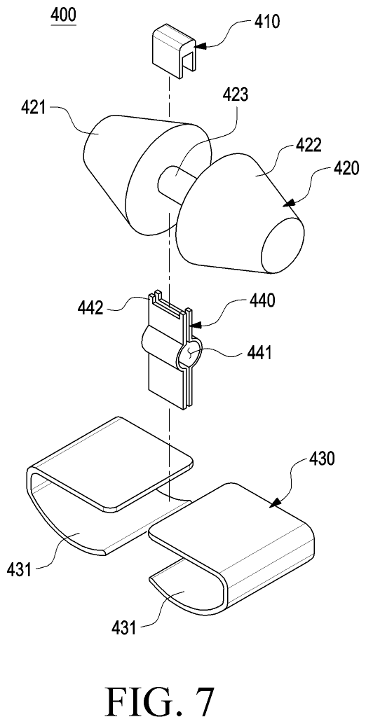

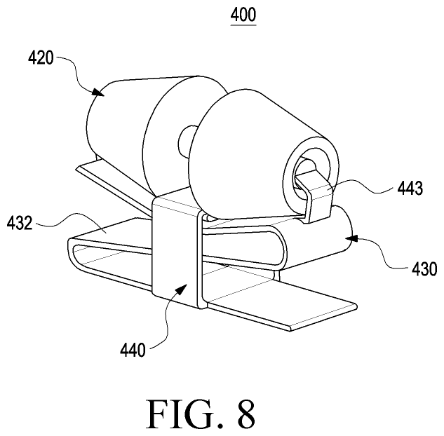

FIG. 6 is a perspective view illustrating an example ground structure according to various embodiments. FIG. 7 is an exploded perspective view illustrating a ground structure according to various embodiments. FIG. 8 is a perspective view illustrating an example ground structure according to various embodiments.

Referring to FIGS. 6, 7 and 8, the ground structure 400 may include a ground area 410, a rotation area 420, an elastic area 430, and/or a supporting frame 440. The configuration of the ground structure 400 of FIGS. 6, 7 and 8 may be identical in whole or part to the configuration of the ground structure 400 of FIGS. 5A and/or 5B.

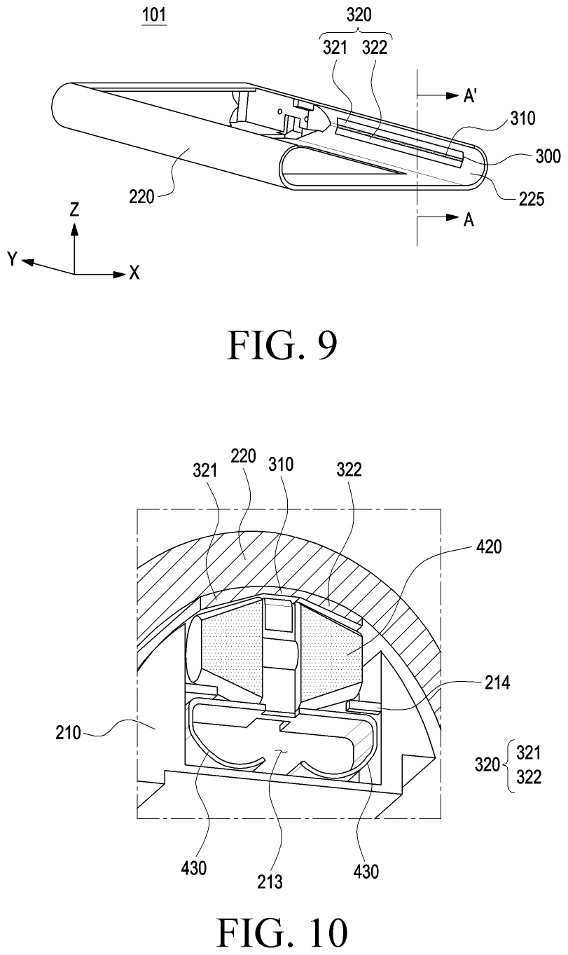

According to an embodiment, the ground area 410 may be electrically connected to the rail structure 300. For example, the ground area 410 may contact the rail structure 300. According to an embodiment, the ground area 410 may slide with respect to the rail structure 300 and/or the second housing (e.g., the second housing 220 of FIG. 5B) while being in surface contact with the rail structure 300. According to an embodiment, the ground area 410 may face a portion (e.g., the first area 310 of FIG. 9) of the rail structure 300. According to an embodiment, the ground area 410 may protrude or extend toward the rail structure (e.g., the rail structure 300 of FIG. 9) as compared to the rotation area 420.

According to an embodiment, the ground area 410 may include a low-friction material. For example, at least a portion of the ground area 410 may include polytetrafluoroethylene (PTFE).

According to an embodiment, the ground area 410 may be connected to the supporting frame 440. The electrical signal transferred to the ground area 410 through the rail structure 300 may be transferred to the elastic area 430 and/or the supporting frame 440.

According to an embodiment, the rotation area 420 may be electrically connected to the rail structure 300. For example, the rotation area 420 may contact the rail structure 300. According to an embodiment, the rotation area 420 may rotate with respect to the rail structure 300 while being in line or surface contact with the rail structure 300. According to an embodiment, the rotation area 420 may face a portion (e.g., the second area 320 of FIG. 9) of the rail structure 300.

According to an embodiment, the rotation area 420 may be connected to the supporting frame 440. The electrical signal transferred to the rotation area 420 through the rail structure 300 may be transferred to the elastic area 430 and/or the supporting frame 440.

According to an embodiment, the rotation area 420 may include a first roller 421 configured to rotate in contact with the second area 320, a second roller 422 spaced apart from the first roller 421 and configured to rotate in contact with the second area 320, and a central area 423 positioned between the first roller 421 and the second roller 422. According to an embodiment, the central area 423 may extend from the first roller 421 to the second roller 422. The central area 423 may be rotatably connected to the supporting frame 440. For example, at least a portion of the central area 423 may be inserted into the receiving hole 441 of the supporting frame 440. According to an embodiment, the rollers 421 and 422 may be excluded. For example, at least a portion of the ground structure 400 may include a low-friction material (e.g., polytetrafluorethylene) and may slide with respect to the rail structure 300 without rotating.

According to an embodiment, the elastic area 430 may provide a force (e.g., an elastic force) for increasing the contact area between the ground structure 400 and the rail structure (e.g., the rail structure 300 of FIG. 9). For example, the elastic area 430 may be compressed or extended (or stretched) while being connected to the supporting frame 440. The elastic area 430 may provide pressure to the first housing (e.g., the first housing 210 of FIG. 4), and the ground area 410 of the ground structure 400 may come in tight contact with the rail structure 300 based on the force (e.g., an elastic force) provided by the elastic area 430. For example, the ground area 410 of the ground structure 400 may provide pressure to the rail structure 300.

According to an embodiment, the elastic area 430 may be formed in various shapes. According to an embodiment (e.g., FIGS. 6 and 7), the elastic area 430 may include a plurality (e.g., two) plates 431 at least partially bent. For example, at least a portion of the plate 431 may be formed in a “C” shape. According to an embodiment (e.g., FIG. 8), the elastic area 430 may include a plate 432 in which at least two portions are bent.

According to an embodiment, the supporting frame 440 may be connected to the ground area 410, the rotation area 420, and the elastic area 430. According to an embodiment (e.g., FIGS. 6 and 7), the supporting frame 440 may include a receiving hole 441 that receives at least a portion (e.g., the central area 423) of the rotation area 420. The central area 423 may rotate in the receiving hole 441. According to an embodiment, the supporting frame 440 may include a protrusion 442 connected to the ground area 410. According to an embodiment (e.g., FIG. 8), the supporting frame 440 may include a connection portion 443 connected to the rotation area 420. The rotation area 420 may be rotatably connected to the connection portion 443.

According to an embodiment, the ground structure 400 may be positioned between the rotation area 420 and the ground frame 440, and may include a bearing or bushing for reducing a frictional force generated when the rotation area 420 rotates.

Referring to FIG. 8, the rotation area 420 and/or the elastic area 430 of the ground structure 400 may be electrically connected to the rail structure 300. For example, the rotation area 420 may slide with respect to the rail structure 300 and/or the second housing (e.g., the second housing 220 of FIG. 5B) while being in contact with the rail structure 300. According to an embodiment, the electrical signal transferred to the rotation area 420 may be transferred to the first housing 210 through the elastic area 430.

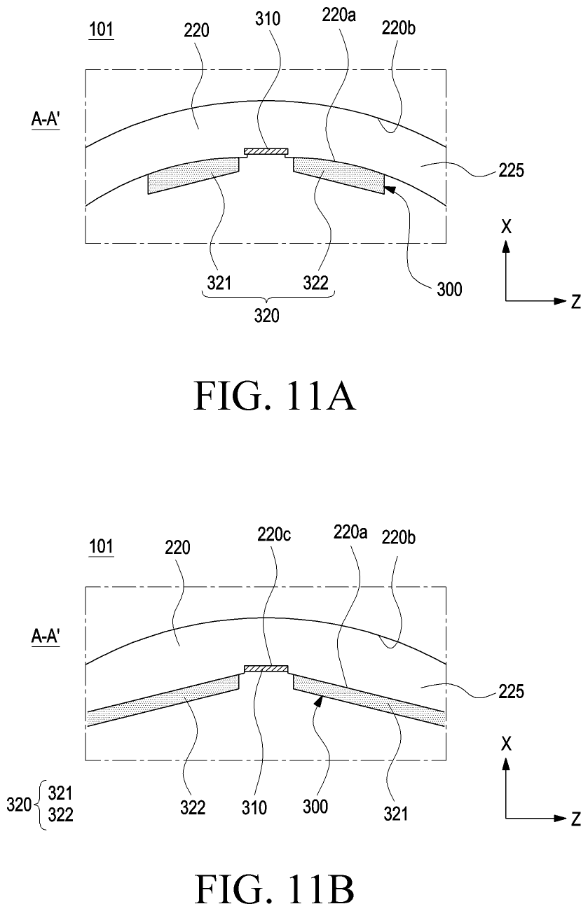

FIG. 9 is a perspective view illustrating an electronic device including a rail structure and a second housing according to various embodiments. FIG. 10 is a cross-sectional view illustrating an electronic device according to various embodiments. FIGS. 11A and 11B are cross-sectional views taken along line A-A′ of FIG. 9 according to various embodiments.

Referring to FIG. 9, FIG. 10, FIG. 11A, and/or FIG. 11B, an electronic device 101 may include a first housing 210, a second housing 220, a rail structure 300, and/or a ground structure 400. The configuration of the first housing 210, the second housing 220, and/or the rail structure 300 of FIG. 9, FIG. 10, FIG. 11A, and/or FIG. 11B may be identical in whole or part to the configuration of the first housing 210, the second housing 220, and/or the rail structure 300 of FIG. 5A. The configuration of the ground structure 400 of FIG. 10 may be identical in whole or part to the configuration of the ground structure 400 of FIG. 6.

According to an embodiment, the ground structure 400 may be disposed in the first housing 210. According to an embodiment, the first housing 210 may include a receiving space 213 for receiving the ground structure 400. For example, at least a portion (e.g., the elastic area 430) of the ground structure 400 may be disposed in the receiving space 213. According to an embodiment, the first housing 210 may include a protrusion 214 for preventing or reducing separation of the ground structure 400. The protrusion 214 may surround at least a portion (e.g., the elastic area 430) of the ground structure 400 and may prevent or inhibit the ground structure 400 from escaping off the first housing 210. According to an embodiment, the receiving space 213 may be interpreted as an empty space at least partially surrounded by the protrusion 214 and the first housing 210. For example, the protrusion 214 may form or define at least a portion of the receiving space 213.

According to an embodiment, the second housing 220 may include an inner wall 225 surrounding at least a portion of the first housing 210. According to an embodiment, the inner wall 225 of the second housing 220 may include a second surface 220b facing outward of the electronic device 101 and a first surface 220a opposite to the second surface 220b and configured to face the first housing 210.

According to an embodiment, the inner wall 225 may be formed in various thicknesses. For example (e.g., FIG. 11A), the thickness of the inner wall 225 may be substantially uniform. As another example (e.g., FIG. 11B), the inner wall 225 may be formed in a shape for guiding the movement of the ground structure 400. For example, the inner wall 225 may include a second surface 220b facing outward of the electronic device 101, a first surface 220a opposite to the second surface 220b and configured to face the first housing 210, and a recessed area 220c recessed from the first surface 220a. The inner wall 225 of FIG. 9 may be identical in whole or part to the configuration of the 2-2th side wall 221b and/or the 2-3th side wall 221c of FIGS. 2 and 3.

According to an embodiment, the rail structure 300 may be disposed on the second housing 220. For example, the rail structure 300 may be disposed on the inner wall 225 of the second housing 220. According to an embodiment, the rail structure 300 may be disposed on the first surface 220a of the second housing 220. According to an embodiment, the rail structure 300 may extend from the inner wall 225 along the sliding direction (e.g., the Y-axis direction) of the electronic device 101. According to an embodiment, the rail structure 300 may be connected to the second housing 220. For example, the rail structure 300 may be attached to the first surface 220a of the second housing 220. As another example, the second housing 220 may include a recess, and at least a portion of the rail structure 300 may be disposed in the recess. According to an embodiment, the rail structure 300 may be integrally formed with the second housing 220. According to an embodiment, the rail structure 300 may include a first area 310 capable of guiding the movement of the ground structure 300. For example, the ground area 410 may slide with respect to the rail structure 300 while being in contact with the first area 310. The first area 310 may face at least a portion (e.g., the ground area 410) of the ground structure 300.

According to an embodiment, the rail structure 300 may include a second area 320. According to an embodiment, the second area 320 may be disposed parallel to the first area 310. According to an embodiment, the second area 320 may include a plurality of areas arranged in parallel. For example, the second area 320 may include a 2-1th area 321 and a 2-2th area 322 arranged parallel to the 2-1th area 321. The first area 310 may be disposed between the 2-1th area 321 and the 2-2th area 322.

According to an embodiment, the rail structure 300 may be formed in a shape for preventing or reducing the separation of the ground structure 400. For example, the second area 320 may be formed to have a thickness different from that of the first area 310. According to an embodiment (e.g., FIGS. 10, 11A, and 11B), the second area 320 may protrude toward the ground structure 300 as compared to the first area 310. For example, the first area 310 may be interpreted as a recess depressed as compared with the second area 320. At least a portion (e.g., the ground area 410) of the ground structure 400 may extend toward the first area 310, and at least a portion of the ground structure 400 may be surrounded by the second area 320. Since the ground area 410 is surrounded by the second area 320, it is possible to prevent or reduce escape of the ground structure 400 off the rail structure 300. According to an embodiment, the thickness of the second area 320 may be larger than the thickness of the first area 310. According to an embodiment (not shown), the first area 310 may protrude toward the ground structure 400 as compared to the second area 320. For example, the first area 310 may be surrounded by the rotation area 420 of the ground structure 400 of FIG. 8, and the second area 320 may contact the rotation area 420 of the ground structure 400 of FIG. 8. The separation of the ground structure 400 may be prevented or reduced by the first area 310 and/or the second area 320.

According to an embodiment, the rail structure 300 may include a material having elasticity. For example, the first area 310 and/or the second area 320 of the rail structure 300 may include a conductive shock absorbing member (e.g., conductive sponge). According to an embodiment, when at least a portion (e.g., the ground area 410 and/or the rotation area 420) of the ground structure 400 contacts the conductive shock absorbing member, the rail structure 300 may be deformable to correspond to the shape of the ground structure 400. According to an embodiment, as the rail structure 300 includes the conductive shock absorbing member, the contact area between the rail structure 300 and the ground structure 400 may be increased, and electrical connectivity between the rail structure 300 and the ground structure 400 may be enhanced.

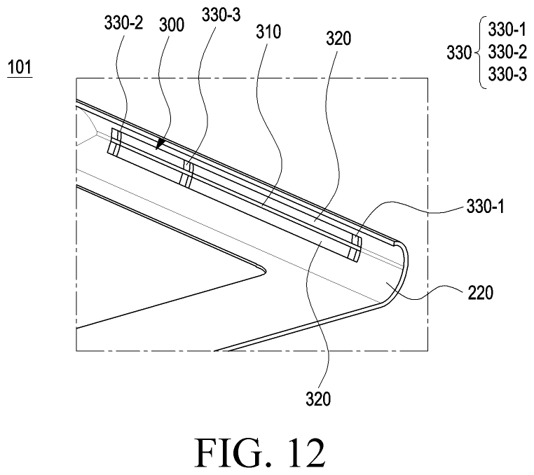

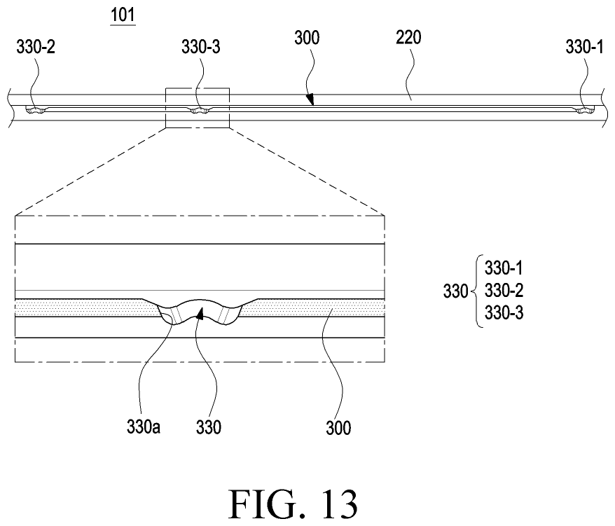

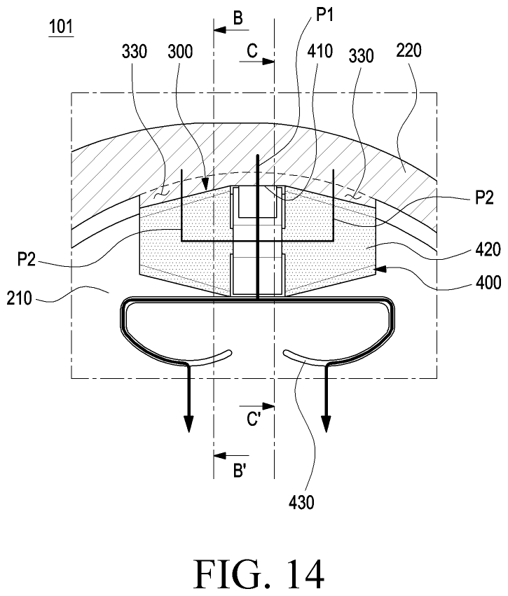

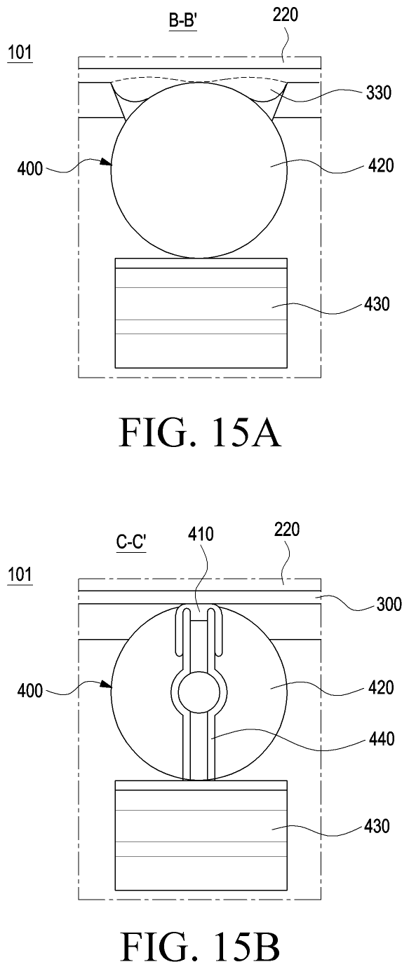

FIG. 12 is a perspective view illustrating an electronic device including a rail structure including a protruding area and a second housing according to various embodiments. FIG. 13 is a diagram illustrating a front view of the rail structure of FIG. 12, according to an various embodiments. FIG. 14 is a cross-sectional view illustrating an electronic device including the rail structure and the second housing of FIG. 12, according to various embodiments. FIG. 15A is a cross-sectional view taken along line B-B′ of FIG. 14 according to various embodiments. FIG. 15B is a cross-sectional view taken along line C-C′ of FIG. 14 according to various embodiments.

Referring to FIG. 12, FIG. 13, FIG. 14, FIG. 15A, and/or FIG. 15B, an electronic device 101 may include a first housing 210, a second housing 220, a rail structure 300, and a ground structure 400. The configuration of the first housing 210, the second housing 220, the rail structure 300, and the ground structure 400 of FIG. 12, FIG. 13, FIG. 14, FIG. 15A, and/or FIG. 15B may be identical in whole or part to the configuration of the first housing 210, the second housing 220, the rail structure 300, and the ground structure 400 of FIG. 5.

According to an embodiment, when a portion of the first housing 210 is positioned inside the second housing, the rail structure 300 may include a protruding portion 330 protruding toward the first housing 210. According to an embodiment, the protruding portion 330 may be formed in a shape corresponding to at least a portion (e.g., the ground area 410 and/or the rotation area 420) of the ground structure 400. As the protruding portion 330 is formed to correspond to the shapes of the ground area 410 and the rotation area 420, the contact area between the rail structure 300 and the ground structure 400 may be increased at a point where the ground structure 400 faces the protruding portion 330. When the contact area between the rail structure 300 and the ground structure 400 is increased, electrical connectivity between the rail structure 300 and the ground structure 400 may be enhanced. According to an embodiment, the protruding portion 330 may be interpreted as a portion of the rail structure 300 protruding from the first area 310 and/or the second area 320 of the rail structure 300.

According to an embodiment, the protruding portion 330 may guide the movement of the ground structure 400. For example, the protruding portion 330 may include a curved portion 330a configured to contact the rotating area 420, and the rotating area 420 may rotate along the curved portion 330a. The protruding portion 330 may be referred to as a portion of the rail structure 300 extending or protruding from the second area 320 of FIG. 12.

According to an embodiment, the protruding portion 330 may protrude toward the first housing 210 at a designated position. According to an embodiment, the protruding portion 330 may include a first protruding portion 330-1 in contact with the ground structure 400 in the state in which the electronic device 101 is completely closed, a second protruding portion 330-2 in contact with the ground structure 400 in the state in which the electronic device 101 is completely open, and/or a third protruding portion 330-3 in contact with the ground structure 400 at a designated position. For example, the protruding portion 330 may face and/or contact at least a portion of the ground structure 400 while the electronic device 101 is in a stationary state. According to an embodiment, each of the first protruding portion 330-1 and the second protruding portion 330-2 may be positioned adjacent to an end portion of the rail structure 300, and the third protruding portion 330-3 may be positioned between the first protruding portion 330-1 and the second protruding portion 330-2. According to an embodiment, a plurality of third protruding portions 330-3 may be present between the first protruding portion 330-1 and the second protruding portion 330-2. According to an embodiment, the ground stability of the electronic device 101 may be increased due to the protruding portion 330. For example, the contact area between the ground structure 400 and the rail structure 300 may be increased due to the protruding portion 330.

According to an embodiment, a ground path including the rail structure 300 and/or the ground structure 400 may be formed. According to an embodiment, a component (e.g., the antenna module 206 of FIG. 5) positioned in the second housing 220 may be electrically connected with the rail structure 300, and the rail structure 300 may be electrically connected with the ground area 410 and/or the rotation area 420, and the ground area 410 and/or the rotation area 420 may be electrically connected with a component (e.g., the ground area of the printed circuit board 204 of FIG. 5A) positioned in the first housing 210. For example, at least a portion of the electrical signal or current received by the rail structure 300 may be transferred (or moved) to a component (e.g., the ground area of the printed circuit board 204 of FIG. 5A) positioned in the first housing 210 through a first conductive path P1 passing through the first area (e.g., the first area 310 of FIG. 9), the ground area 410, and the elastic area 430, and at least a portion of the electrical signal or current received by the rail structure 300 may be transferred (or moved) to a component (e.g., the ground area of the printed circuit board 204 of FIG. 5A) positioned in the first housing 210 through a second conductive path P2 passing through the second area (e.g., the second area 320 of FIG. 9), the rotation area 420, and the elastic area 430.

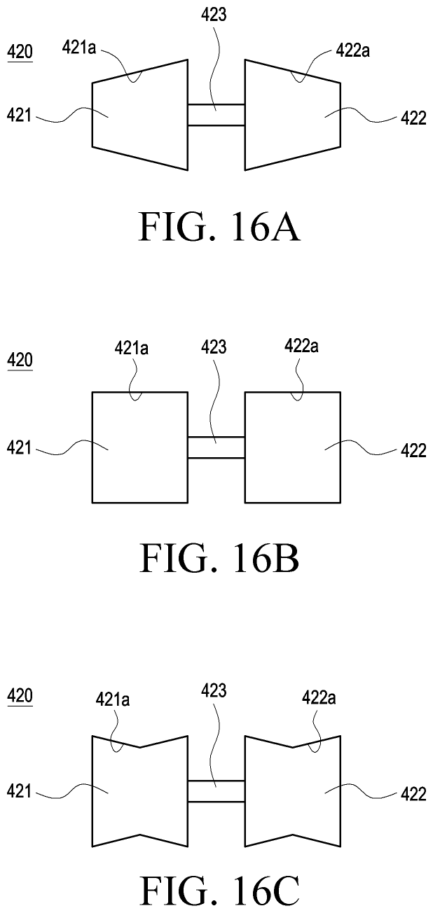

FIGS. 16A, 16B, and 16C are diagrams illustrating examples of a rotation area of a ground structure according to various embodiments.

Referring to FIGS. 16A, 16B, and 16C, the rotation area 420 may be formed in various shapes. The configuration of the rotation area 420 of FIGS. 16A, 16B, and 16C may be identical in whole or part to the configuration of the rotation area 420 of FIG. 6.

According to an embodiment, the rotation area 420 may include a first roller 421 and a second roller 422 to face the rail structure (e.g., the rail structure 400 of FIG. 8). According to an embodiment, the rotation area 420 may include a central area 423 connected to the first roller 421 and the second roller 422. According to an embodiment, the first roller 421 may be formed to be symmetrical to the second roller 422 with respect to the central area 423. The configuration of the first roller 421, the second roller 422, and the central area 423 of FIGS. 16A, 16B, and 16C may be identical in whole or part to the configuration of the first roller 421, the second roller 422, and the central area 423 of FIG. 7.

According to an embodiment, the rollers 421 and 422 may be formed in various shapes. According to an embodiment (e.g., FIG. 16A), the first roller 421 and the second roller 422 may be formed in a truncated cone shape. For example, the first roller surface 421a of the first roller 421 and the second roller surface 422a of the second roller 422 may be inclined planes of the truncated cone. According to an embodiment (e.g., FIG. 16B), the first roller 421 and the second roller 422 may be formed in a cylindrical shape. For example, the second roller surface 422a of the second roller 422 of the first roller 421 may be the inclined planes of the cylinder. According to an embodiment (e.g., FIG. 16C), at least a portion of the first roller 421 and the second roller 422 may be bent or inclined. For example, at least a portion of the first roller surface 421a of the first roller 421 and the second roller surface 422a of the second roller 422 may be bent or inclined. The shape of the rotation area 420 according to various embodiments of the disclosure is not limited to the shapes disclosed in FIGS. 16A, 16B, and 16C. For example, when the first roller surface 421a and the second roller surface 422a contact at least a portion of the second area (e.g., the second area 420 of FIG. 8) of the rail structure 400, the rotation area 420 may be formed in various shapes. According to various embodiments, the shape of the rotation area 420 may be formed in various shapes based on the shape of the inner wall (e.g., the inner wall 225 of FIG. 9) of the second housing in which the rail structure 400 is positioned and/or the shape of the rail structure 400. According to an embodiment (not shown), the first roller 421 and the second roller 422 of the rotation area 420 may be formed in an asymmetric shape. For example, the size of the diameter of the first roller 421 and the size of the diameter of the second roller 422 may be different. As another example, the shape of the first roller 421 and the shape of the second roller 422 may be different.

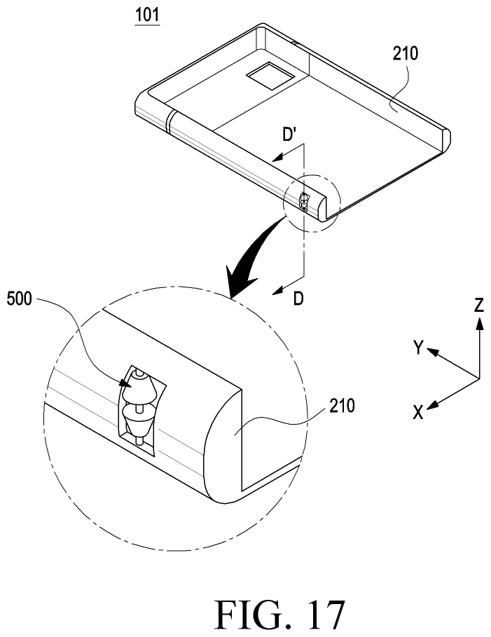

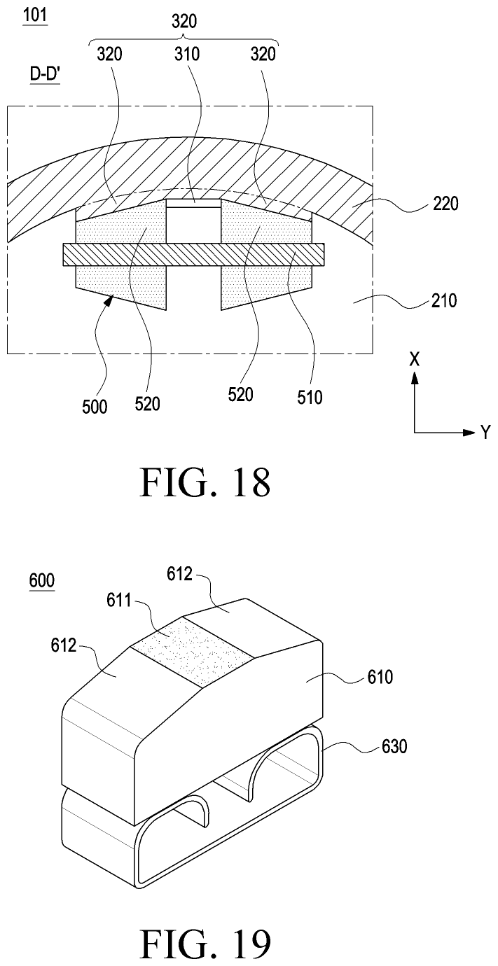

FIG. 17 is a perspective view illustrating an electronic device including a ground structure and a first housing according to various embodiments. FIG. 18 is a cross-sectional view illustrating an electronic device including a ground structure and a first housing according to various embodiments. For example, FIG. 18 is a cross-sectional view of an electronic device 101 including a second housing 220, a first housing 210, and a ground structure 500, which are taken along line D-D′ of FIG. 17.

Referring to FIG. 17 and/or FIG. 18, the electronic device 101 may include a first housing 210, a second housing 220, a rail structure 300, and a ground structure 500. The configuration of the first housing 210, the second housing 220, the rail structure 300, and the ground structure 500 of FIG. 17 and/or FIG. 18 may be identical in whole or part to the configuration of the first housing 210, the second housing 220, the rail structure 300, and the ground structure 400 of FIG. 5A.

According to an embodiment, the ground structure 500 may slide with respect to the second housing 220 while being connected to the first housing 210. For example, the ground structure 500 may move along the rail structure 300 while being in contact with the rail structure 300.

According to an embodiment, the ground structure 500 may include a shaft 510 connected to the first housing 210. At least a portion of the shaft 510 may include a conductive material, and may be electrically connected to a ground area (e.g., the ground area of the printed circuit board 204 of FIG. 5A) positioned in the first housing 210.

According to an embodiment, the ground structure 500 may include a rotation area 520 rotatably connected to the shaft 510. According to an embodiment, the rotation area 520 may rotate along the rail structure 300 while being in contact with at least a portion (e.g., the second area 320) of the rail structure 300. At least a portion of the rotation area 520 may include a conductive material and may be electrically connected to the first shaft 510. According to an embodiment, the rotation area 520 may be electrically connected to at least a portion (e.g., the second area 320) of the rail structure 300 and the first shaft 510.

According to an embodiment, the second area 320 of the rail structure 300 may include a material having elasticity. For example, the second area 320 may include a conductive shock absorbing member (e.g., conductive sponge). According to an embodiment, as the second area 320 includes the conductive shock absorbing member, the contact area between the rail structure 300 and the ground structure 500 may be increased, and electrical connectivity between the rail structure 300 and the ground structure 500 may be enhanced.

According to an embodiment, the first area 310 and the second area 320 may be integrally formed with each other. For example, the first area 310 may be referred to as a portion of the rail structure 300 protruding from the second area 320. According to an embodiment (not shown), the first area 310 may be excluded from the rail structure 300. For example, the rail structure 300 may include a plurality of second areas 320, and the ground structure 500 may contact the plurality of second areas 320.

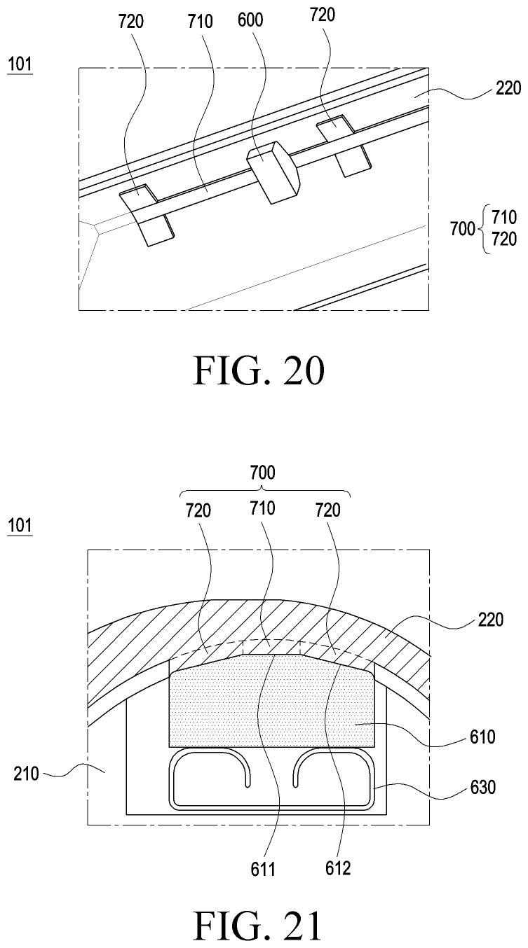

FIG. 19 is a perspective view illustrating an example ground structure according to various embodiments. FIG. 20 is a perspective view illustrating an electronic device including a ground structure and a second housing including a rail structure according to various embodiments. FIG. 21 is a cross-sectional view illustrating an electronic device according to various embodiments.

Referring to FIGS. 19, 20, and/or 21, an electronic device 101 may include a first housing 210, a second housing 220, a ground structure 600, and/or a rail structure 700. The configuration of the first housing 210, the second housing 220, the ground structure 600, and the rail structure 700 of FIG. 19, FIG. 20, and/or FIG. 21 may be identical in whole or part to the configuration of the first housing 210, the second housing 220, the ground structure 600, and the rail structure 700 of FIG. 5A.

According to an embodiment, the ground structure 600 may include a ground area 610 (e.g., the ground area 610 of FIG. 6) and an elastic area 630 (e.g., the elastic area 430 of FIG. 6). According to an embodiment, the ground area 610 may be formed of a conductive material, may contact the rail structure 700, and may be electrically connected to the rail structure 700. According to an embodiment, the ground area 610 may include a first ground surface 611 facing the first area 710 of the rail structure 700 and at least one second ground surface 612 extending from the first area 710. For example, the second ground surface 612 may be referred to as a surface extending from two opposite end portions of the first ground surface 611. According to an embodiment, the shape (e.g., slope) of the first ground surface 611 and the at least one second ground surface 612 may be formed based on the shape of the inner wall (e.g., the inner wall 225 of FIG. 9) of the second housing.

According to an embodiment, the rail structure 700 may include a first area 710 and a third area 720 extending from the first area 710. The first area 710 may extend along a sliding direction of the electronic device 101 (or the first housing 210). The third area 720 may be formed in a shape corresponding to the shape of at least a portion (e.g., the second ground surface 612) of the ground structure 600. As the third area 720 is formed to correspond to the shape of the ground area 610, the contact area between the rail structure 700 and the ground structure 600 may be increased at a point where the ground structure 600 faces the third area 720. When the contact area between the rail structure 700 and the ground structure 600 is increased, electrical connectivity between the rail structure 700 and the ground structure 600 may be enhanced. According to an embodiment, as the third area 720 is formed at a designated position for the electronic device 101 to stop, the frictional force between the ground structure 600 and the rail structure 700 may be reduced, and the electrical connectivity between the rail structure 700 and the ground structure 600 may be enhanced.

According to an embodiment, various positions may be set for the third area 720. For example, the third area 720 may be positioned to contact the ground structure 600 in the completely closed state of the electronic device 101, to contact the ground structure 600 in the completely open state of the electronic device 101, or to contact the ground structure 600 at a designated position. According to an embodiment, when the ground structure 600 contacts the third area 720, electrical connectivity between the ground structure 600 and the rail structure 700 may be enhanced.

An electronic device (e.g., a portable terminal) includes a display with a flat surface or both a flat and curved surface. An electronic device including a display may have a limitation in realizing a screen larger than the size of the electronic device due to the fixed display structure. Accordingly, research has been conducted on electronic devices including a rollable display.

An electronic device including a rollable display may include a plurality of housings that move relative to each other. However, when the conductive components disposed in the plurality of housings, respectively, overlap each other, parasitic resonance may occur and antenna radiation performance may be reduced.

According to an embodiment of the disclosure, there may be provided an electronic device including a rail structure and a ground structure, which may reduce parasitic resonance and increase the area of the ground by electrically connecting components disposed in different housings. In the disclosure, ground may also be referred to as an earth.

The disclosure is not limited to the foregoing example embodiments but various modifications or changes may rather be made thereto without departing from the spirit and scope of the disclosure.

According to an example embodiment of the disclosure, a component (e.g., an antenna) disposed in the second housing and a component (e.g., a printed circuit board) disposed in the first housing may be electrically connected using a rail structure and a ground structure. As components disposed in different housings are electrically connected, parasitic resonance generated due to an overlap between metal components in the closed state of the electronic device may be reduced, and the size of the ground may be increased, thereby increasing the radiation performance of the antenna.

According to various example embodiments of the disclosure, an electronic device (e.g., the electronic device 101 of FIG. 2) may comprise: a housing (e.g., the first housing 201 of FIG. 2) including a second housing (e.g., the second housing 220 of FIG. 2) and a first housing (e.g., the first housing 220 of FIG. 2) slidable with respect to the second housing, a display (e.g., the display 230 of FIG. 2) configured so that at least a portion thereof is extended based on the slide of the first housing, a printed circuit board (e.g., the printed circuit board 204 of FIG. 4) disposed in the housing, a ground structure including a conductive material (e.g., the ground structure 400 of FIG. 5A) including an elastic area (e.g., the elastic area 430 of FIG. 6 or 8) configured to provide a force to the first housing and electrically connecting the printed circuit board and the second housing, and at least one rail structure including a rail (e.g., the rail structure 300 of FIG. 9) disposed, inside (e.g., on the inner wall 225 of FIG. 9) the second housing, parallel to a sliding direction of the first housing and configured to contact the ground structure while the first housing is in a state of sliding with respect to the second housing or in a stationary state. The at least one rail structure may include a first area (e.g., the first area 310 of FIG. 9) and a second area (e.g., the second area 320 of FIG. 9) protruding toward the ground structure as compared with the first area.

According to an example embodiment, the rail structure may be configured to contact at least a portion of the ground structure based on the first housing being in the stationary state and may include at least one protruding portion (e.g., the protruding portion 330 of FIG. 12) protruding toward the first housing.

According to an example embodiment, the ground structure may include a ground area (e.g., the ground area 410 of FIG. 6) facing the first area and configured to slide along the first area.

According to an example embodiment, the ground structure may include a rotation area (e.g., the rotation area 420 of FIG. 6) facing the second area and configured to move along the second area.

According to an example embodiment, the ground structure may include a supporting frame (e.g., the supporting frame 440 of FIG. 6) configured to receive the rotation area and an elastic area (e.g., the elastic area 430 of FIG. 6) extending from the supporting frame and configured to provide a force to the first housing.

According to an example embodiment, the first housing may include a receiving space (e.g., the receiving space 213 of FIG. 10) configured to receive at least a portion of the ground structure and a protrusion (e.g., the protrusion 214 of FIG. 10) forming at least a portion of the receiving space an configured to inhibit the ground structure from escaping.

According to an example embodiment, a size of an area in which the ground structure contacts the first area may be larger than a size of an area in which the ground structure contacts the second area. For example, the ground structure may be substantially in surface contact with the first area, and the rotation area (e.g., the rotation area 420 of FIG. 6) of the ground structure may be substantially in line contact with the second area.

According to an example embodiment, the second area may include a first second area (e.g., the 2-1th area 321 of FIG. 9) and a second second area (e.g., the 2-2th area 322 of FIG. 9) spaced apart from the first second area. The first area may be disposed between the first second area and the second second area.

According to an example embodiment, the first housing may include a first portion (e.g., the first portion 210a of FIG. 5B) facing outward of the electronic device and a second portion (e.g., the second portion 210b of FIG. 5B) opposite to the first portion and facing the second housing. The ground structure may be connected to the second portion.

According to an example embodiment, the rail structure may include a conductive shock absorbing member comprising a conductive material facing the ground structure.

According to an example embodiment, the electronic device may further comprise an antenna module including an antenna (e.g., the antenna module 206 of FIG. 5A) connected to the second housing. The antenna module may be electrically connected to a ground layer of the printed circuit board using the ground structure and the rail structure. The ground layer of the printed circuit board may include a metal layer positioned in the printed circuit board.

According to an example embodiment, at least a portion of the ground structure and at least a portion of the rail structure may comprise a conductive material.

According to an example embodiment, the first housing may include a first first sidewall (e.g., the 1-1th sidewall 211a of FIG. 3) facing outward of the electronic device, a second first sidewall (e.g., the 1-2th sidewall 211b of FIG. 3) extending from the first first sidewall, and a third first sidewall (e.g., the 1-3th sidewall 211c of FIG. 3) extending from the first first sidewall and disposed parallel to the second first sidewall, and the second housing may include a first second sidewall (e.g., the 2-1th sidewall 221a of FIG. 3) facing outward of the electronic device, a second second sidewall (e.g., the 2-2th sidewall 221b of FIG. 3) extending from the first second sidewall and facing at least a portion of the second first sidewall, and a third second sidewall (e.g., the 2-3th sidewall 221c of FIG. 3) extending from the first second sidewall and facing at least a portion of the third first sidewall.

According to an example embodiment, the rail structure may include a first rail structure (e.g., the first rail structure 300-1 of FIG. 5A) disposed on the second second sidewall and a second rail structure (e.g., the second rail structure 300-2 of FIG. 5A) disposed on the third second sidewall, and the ground structure may include a first ground structure (e.g., the first ground structure 400-1 of FIG. 5A) facing at least a portion of the first rail structure and a second ground structure (e.g., the first ground structure 400-2 of FIG. 5A) facing at least a portion of the second rail structure.

According to an example embodiment, the ground structure may be configured to move with respect to the rail structure while contacting at least a portion of the rail structure.

According to an example embodiment, the electronic device may further comprise a multi-bar structure including a plurality of bars configured to support the display. The second housing may include a guide rail (e.g., the guide rail 224 of FIG. 4) for guiding a movement of the multi-bar structure.

According to various example embodiments of the disclosure, an electronic device (e.g., the electronic device 101 of FIG. 2) may comprise: a housing (e.g., the housing 201 of FIG. 2) including a first housing (e.g., the first housing 210 of FIG. 1) and a second housing (e.g., the second housing 220 of FIG. 2) configured to guide a slide of the first housing, a display (e.g., the display 230 of FIG. 2) configured so that at least a portion thereof is not foldable based on sliding of the first housing, a printed circuit board (e.g., the printed circuit board 204 of FIG. 4) disposed in the first housing, a ground structure comprising a conductive material (e.g., the ground structure 400 of FIG. 6) connected to the first housing and electrically connected to the printed circuit board, and a rail structure including at least one rail (e.g., the rail structure 300 of FIG. 9) connected to the second housing and configured to guide the slide of the first housing with respect to the second housing. The rail structure may include a protruding portion (e.g., the protruding portion 330 of FIG. 13) protruding toward the first housing and formed to correspond to a shape of the ground structure.

According to an example embodiment, the rail structure may include a first area (e.g., the first area 310 of FIG. 9) and a second area (e.g., the second area 310 of FIG. 9) disposed parallel to the first area. A thickness of the second area in a width direction (e.g., X-axis direction of FIG. 9) of the electronic device may be greater than a thickness of the first area in the width direction.

According to an example embodiment, the second area may include a first second area (e.g., the 2-1th area 321 of FIG. 9) and a second second area (e.g., the 2-2th area 322 of FIG. 9) spaced apart from the first second area. The first area may be disposed between the first second area and the second second area.

According to an example embodiment, the ground structure may include a ground area (e.g., the ground area 410 of FIG. 6) facing the first area and configured to slide along the first area and a rotation area (e.g., the rotation area 420) facing the second area and configured to move along the second area.

According to an example embodiment, the electronic device may further comprise an antenna module including an antenna (e.g., the antenna module 206 of FIG. 5A) connected to the second housing. The antenna module may be electrically connected to the printed circuit board using the ground structure and the rail structure.

It is apparent to one of ordinary skill in the art that an electronic device including a ground structure as described above are not limited to the above-described embodiments and those shown in the drawings, and various changes, modifications, or alterations may be made thereto without departing from the scope of the disclosure, including the appended claims and their equivalents. It will also be understood that any of the embodiment(s) described herein may be used in conjunction with any other embodiment(s) described herein.

What is claimed is:

1. An electronic device, comprising:
a housing including a second housing and a first housing configured to be slidable with respect to the second housing;
a display, wherein at least a portion of the display is configured to be unfolded based on a slide movement of the first housing;
a printed circuit board disposed in the housing;
a ground structure comprising a conductive material and including an elastic area configured to provide a force to the first housing and electrically connecting the printed circuit board and the second housing; and
at least one rail structure comprising a rail disposed in the second housing parallel to a direction of the slide movement of the first housing and configured to contact the ground structure while the first housing is in a state of sliding with respect to the second housing or in a stationary state,
wherein the at least one rail structure includes a first area and a second area protruding toward the ground structure as compared with the first area.

2. The electronic device of claim 1, wherein the rail structure is configured to contact at least a portion of the ground structure based on the first housing being in the stationary state and includes at least one protruding portion protruding toward the first housing.

3. The electronic device of claim 1, wherein the ground structure includes a ground area facing the first area and configured to slide along the first area.

4. The electronic device of claim 1, wherein the ground structure includes a rotation area facing the second area and configured to move along the second area.

5. The electronic device of claim 1, wherein the ground structure includes a supporting frame configured to receive the rotation area and an elastic area extending from the supporting frame and configured to provide a force to the first housing.

6. The electronic device of claim 1, wherein the first housing includes a receiving space configured to receive at least a portion of the ground structure and a protrusion forming at least a portion of the receiving space and configured to inhibit the ground structure from escaping.

7. The electronic device of claim 1, wherein a size of an area in which the ground structure contacts the first area is greater than a size of an area in which the ground structure contacts the second area.

8. The electronic device of claim 1, wherein the first housing includes a first portion facing outward of the electronic device and a second portion opposite to the first portion and facing the second housing, and
wherein the ground structure is connected to the second portion.

9. The electronic device of claim 1, wherein the rail structure includes a conductive shock absorbing member comprising a conductive material configured to be deformable corresponding to a shape of the ground structure.

10. The electronic device of claim 1, further comprising an antenna module comprising an antenna connected to the second housing,
wherein the antenna module is electrically connected to a ground layer of the printed circuit board using the ground structure and the rail structure.

11. The electronic device of claim 1, wherein at least a portion of the ground structure and at least a portion of the rail structure comprise a conductive material.

12. The electronic device of claim 1, wherein the first housing includes a first first sidewall facing outward of the electronic device, a second first sidewall extending from the first first sidewall, and a third first sidewall extending from the first first sidewall and disposed parallel to the second first sidewall, and
wherein the second housing includes a first second sidewall facing outward of the electronic device, a second second sidewall extending from the first second sidewall and facing at least a portion of the second first sidewall, and a third second sidewall extending from the first second sidewall and facing at least a portion of the third first sidewall.

13. The electronic device of claim 12, wherein the rail structure includes a first rail structure disposed on the second second sidewall and a second rail structure disposed on the third second sidewall, and
wherein the ground structure includes a first ground structure facing at least a portion of the first rail structure and a second ground structure facing at least a portion of the second rail structure.

14. The electronic device of claim 1, wherein the ground structure is configured to move with respect to the rail structure while contacting at least a portion of the rail structure.

15. The electronic device of claim 1, further comprising a multi-bar structure comprising a plurality of bars configured to support the display,
wherein the second housing includes a guide rail configured to guide a movement of the multi-bar structure.
